(19) United States
(12) Patent Application Publication
(10) Pub. No.: US 2006/0022766 A1
(43) Pub. Date: Feb. 2, 2006

(54) High frequency circuit module having non-reciprocal circuit element

(75) Inventors: Isao Ishigaki, Tokyo (JP); Yasumichi Wakita, Tokyo (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/192,388

(22) Filed: Jul. 28, 2005

(30) Foreign Application Priority Data
Jul. 30, 2004 (JP) 2004-224033

(51) Int. Cl. H01P 1/32; H03H 9/72

(52) U.S. Cl. 333/1.1; 333/24.2; 333/133

(57) ABSTRACT

A high frequency circuit module having a non-reciprocal circuit element includes a circuit substrate that is composed of a multilayer substrate; and a high frequency circuit element having the non-reciprocal circuit element provided on the circuit substrate. The non-reciprocal circuit element includes a lower yoke composed of ferromagnetic membranes formed in the accommodating portion of the circuit substrate and the bottom surface; a ferrite member accommodated in the accommodating portion; first, second and third central conductors disposed on the ferrite member via a dielectric; a magnet; and an upper yoke disposed to cover the magnet and the accommodating portion. When the lower yoke is formed of the ferromagnetic membrane, the number of essential elements is less, productivity is high, a cost is low, and the non-reciprocal circuit element has a small size in a thickness direction, compared to a conventional lower yoke made of a metal plate.

### BACKGROUND OF THE INVENTION

1. Field of the Invention

The present invention relates to a high frequency circuit module having a non-reciprocal circuit element suitably used for an antenna duplexer.

2. Description of the Related Art

A high frequency circuit module having a conventional non-reciprocal circuit element will be described with reference to the accompanying drawings. FIG. 19 is an exploded perspective view showing a high frequency circuit module having a conventional non-reciprocal circuit element in a state in which an upper yoke is removed. FIG. 20 is a cross-sectional view showing the high frequency circuit module having the conventional non-reciprocal circuit element.

Next, the structure of the high frequency circuit module having the conventional non-reciprocal circuit element will be described with reference to FIGS. 19 and 20. A circuit substrate 50 is composed of a multilayer substrate in which a plurality of insulating plates are laminated. The circuit substrate 50 has a circular through hole 50a, a recess 50b formed around the through hole 50a, a plurality of holes 50c formed downward from the bottom of the recess 50b, and a pair of rectangular holes 50d with the though hole 50a interposed therebetween.

A wiring pattern 51 is formed in the circuit substrate 50, a capacitor 52 is formed on the circuit substrate 50, and the capacitor 52 is connected to the wiring pattern 51 formed between laminated layers via a connection conductor 53.

A U-shaped lower yoke 54 is formed of a bent metal plate made of a ferromagnetic material. The U-shaped lower yoke 54 has a bottom plate 54a and a pair of side plates 54b bent from the bottom plate 54a. The U-shaped lower yoke 54 is attached to the circuit substrate 50 by inserting the pair of side plates 54b into the holes 50d of the circuit substrate 50 so as to cover the bottom of the through hole 50a with the bottom plate 54a.

A discoidal ferrite member 55 is accommodated in the through hole 50a, so that the bottom of the ferrite member 55 comes into contact with the bottom plate 54a.

A plurality of central conductors 58 are formed on one surface of an insulating substrate 56 in a type of thin films, such that portions of them cross each other in a vertical direction via a dielectric 57. In a state in which the insulating substrate 56 having the central conductors 58 is reversed in order for the central conductors 58 to face downward, the central conductors 58 are located in the recess 50b, so that the central conductors 58 are mounted on the ferrite member 55.

In this state, port portions 58a of the central conductors 58 are connected to the wiring pattern 51 located between laminated layers by connection conductors 59 filled in the holes 50c. Grounding portions 58b of the central conductors 58 are connected to the bottom plate 54a of the lower yoke 54 by connection conductors 60 filled in the holes 50c, so that they are electrically connected to the ground.

A magnet 61 is mounted on the insulating substrate 56, a U-shaped upper yoke 62 formed of a bent metal plate made of a ferromagnetic material has a top plate 62a and side plates 62b bent from the top plate 62a. In the upper yoke 62, the side plate 62b is coupled with the side plate 54b of the lower yoke 54 in a state that the magnet 61 is covered with the top plate 62a, and the upper yoke 62 and the lower yoke 54 form a magnetic closed circuit. As a result, the conventional non-reciprocal circuit element is formed.

The high frequency circuit module having the conventional non-reciprocal circuit element constructed in this way can be miniaturized in the vertical direction (a thickness direction) by accommodating the ferrite member 55 of the non-reciprocal circuit element in the circuit substrate 50. However, the lower yoke 54 made of a metal plate and the insulating substrate 56 that forms the central conductors 58 are required. Therefore, the number of essential elements increases, which not only leads to bad productivity and a high cost, but also leads to a non-reciprocal circuit element having a large size in the thickness direction.

In addition, the port portions 58a of the central conductors 58 are connected to the wiring pattern 51 located in the laminated layers via the connection conductors 59 in the state in which the insulating substrate 56 is reversed. Since the grounding portions 58b of the central conductors 58 are connected to the bottom plate 54a located at the bottom via the connection conductors 60, the structure is complicated and the productivity is deteriorated as well.

The high frequency circuit module having the conventional non-reciprocal circuit element can be miniaturized in the vertical direction (a thickness direction) by accommodating the ferrite member 55 of the non-reciprocal circuit element in the circuit substrate 50. However, the lower yoke 54 made of a metal plate and the insulating substrate 56 that forms the central conductors 58 are required. Therefore, the number of essential elements increases, which not only leads to bad productivity and a high cost, but also leads to a non-reciprocal circuit element having a large size in the thickness direction.

The port portions 58a of the central conductors 58 are connected to the wiring pattern 51 located in the laminated layers via the connection conductors 59 in the state in which the insulating substrate 56 is reversed. Since the grounding portions 58b of the central conductors 58 are connected to the bottom plate 54a located at the bottom via the connection conductors 60, the structure is complicated and the productivity is deteriorated as well.

### SUMMARY OF THE INVENTION

An advantage of the invention is that it provides a high frequency circuit module having a non-reciprocal circuit element which can be manufactured at a low cost with high productivity and a small size.

According to a first aspect of the invention, there is provided a high frequency circuit module having a non-reciprocal circuit element, including: a circuit substrate that has a wiring pattern and that is composed of a multilayer substrate in which a plurality of insulating plates are laminated; a high frequency circuit element having the non-reciprocal circuit element provided on the circuit substrate; and a high frequency circuit formed on the circuit substrate. In addition, an accommodating portion composed of a recess having a bottom surface is provided in the circuit substrate; and the non-reciprocal circuit element includes a lower yoke composed of ferromagnetic membranes formed on a side surface of the accommodating portion and the bottom surface; a ferrite member accommodated in the accommodating portion; first, second and third central conductors disposed on the ferrite member such that portions of the first, second and third central conductors cross each other vertically via a dielectric; a magnet disposed on the first, second and third central conductors such that the first, second and third central conductors are interposed between the ferrite member and the magnet; and an upper yoke disposed to cover the magnet and the accommodating portion for forming a magnetic closed circuit together with the lower yoke.

Further, it is preferable that the lower yoke be formed by performing iron plating.

Further, it is preferable that silver plating be performed on the lower yoke which has been subjected to the iron plating.

Further, it is preferable that a ferromagnetic membrane made of the same material as the lower yoke be formed on the surface of the circuit substrate located in the vicinity of an outer periphery of the accommodating portion, and the upper yoke be coupled at a location of the ferromagnetic membrane.

Further, it is preferable that the central conductors and the dielectric be formed on the ferrite member directly by thick films.

Further, it is preferable that each of the central conductors have a port portion extending from one end of each central conductor and a grounding portion extending from the other end of each central conductor, the port portion and the grounding portion be formed on a side surface of the ferrite member, and the grounding portion be connected to the lower yoke.

Further, it is preferable that the ferrite member be formed of a rectangular plate, and the port portion and the grounding portion are formed on the side surfaces of the ferrite member facing each other.

Further, it is preferable that a plurality of connection patterns, which are not electrically connected to the lower yoke, be formed on the bottom surface of the accommodating portion, a plurality of capacitors, which are respectively connected to the plurality of connection patterns, are formed in the circuit substrate, and the port portion be connected to the connection pattern.

Further, it is preferable that the capacitor be formed on the surface of the circuit substrate, and the capacitor and the connection pattern be connected to each other by a connection conductor formed in an inner layer of the circuit substrate.

Further, it is preferable that the high frequency circuit element have a duplexer composed of a surface acoustic wave element, and the duplexer is mounted on the circuit substrate, thereby constructing an antenna duplexer serving as an transmitting and receiving antenna.

### BRIEF DESCRIPTION OF THE DRAWINGS

FIG. 1 is a plan view showing a main body according to a first embodiment of a high frequency circuit module having a non-reciprocal circuit element of the invention;

FIG. 2 is a cross-sectional view showing a main body according to the first embodiment of the high frequency circuit module having the non-reciprocal circuit element of the invention;

FIG. 3 is a plan view of a main body showing a state in which an upper yoke and a magnet are removed, according to the first embodiment of the high frequency circuit module having the non-reciprocal circuit element of the invention;

FIG. 4 is a plan view of a circuit substrate showing a state of an accommodating portion, according to the first embodiment of the high frequency circuit module having the non-reciprocal circuit element of the invention;

FIG. 5 is a perspective view of the main body of the circuit substrate showing the state of the accommodating portion, according to the first embodiment of the high frequency circuit module having the non-reciprocal circuit element of the invention;

FIG. 6 is a perspective view of a ferrite member, according to the first embodiment of the high frequency circuit module having the non-reciprocal circuit element of the invention;

FIG. 7 is a perspective view showing a state in which the ferrite member is reversed, according to the first embodiment of the high frequency circuit module having the non-reciprocal circuit element of the invention;

FIG. 8 is an equivalent circuit diagram of a non-reciprocal circuit element composed of an isolator, according to the high frequency circuit module having the non-reciprocal circuit element of the invention;

FIG. 9 is an equivalent circuit diagram of a non-reciprocal circuit element composed of a circulator, according to the high frequency circuit module having the non-reciprocal circuit element of the invention;

FIG. 10 is a circuit diagram showing a case in which the high frequency circuit module having the non-reciprocal circuit element of the invention is applied to an antenna duplexer;

FIG. 11 is a plan view of a large-sized ferrite member for describing a method of manufacturing the non-reciprocal circuit element, according to the first embodiment of the high frequency circuit module having the non-reciprocal circuit element of the invention;

FIG. 12 is a bottom view of the large-sized ferrite member for describing the method of manufacturing the non-reciprocal circuit element, according to the first embodiment of the high frequency circuit module having the non-reciprocal circuit element of the invention;

FIG. 13 is a perspective view for describing the method of manufacturing the non-reciprocal circuit element, according to the first embodiment of the high frequency circuit module having the non-reciprocal circuit element of the invention;

FIG. 14 is a perspective view of the ferrite member, according to a second embodiment of the high frequency circuit module having the non-reciprocal circuit element of the invention;

FIG. 15 is a perspective view showing a state in which the ferrite member is reversed, according to the second embodiment of the high frequency circuit module having the non-reciprocal circuit element of the invention;

FIG. 16 is a plan view of a large-sized ferrite member for describing the method of manufacturing the non-reciprocal circuit element, according to the second embodiment of the high frequency circuit module having the non-reciprocal circuit element of the invention;

FIG. 17 is a bottom view of the large-sized ferrite member for describing the method of manufacturing the non-reciprocal circuit element, according to the second embodiment of the high frequency circuit module having the non-reciprocal circuit element of the invention;

FIG. 18 is a perspective view for describing the method of manufacturing the non-reciprocal circuit element, according to the second embodiment of the high frequency circuit module having the non-reciprocal circuit element of the invention;

FIG. 19 is an exploded perspective view showing a state in which an upper yoke is removed, according to a high frequency circuit module having a conventional non-reciprocal circuit element; and

FIG. 20 is a cross-sectional view of the high frequency circuit module having the conventional non-reciprocal circuit element;

### DESCRIPTION OF THE PREFERRED EMBODIMENT

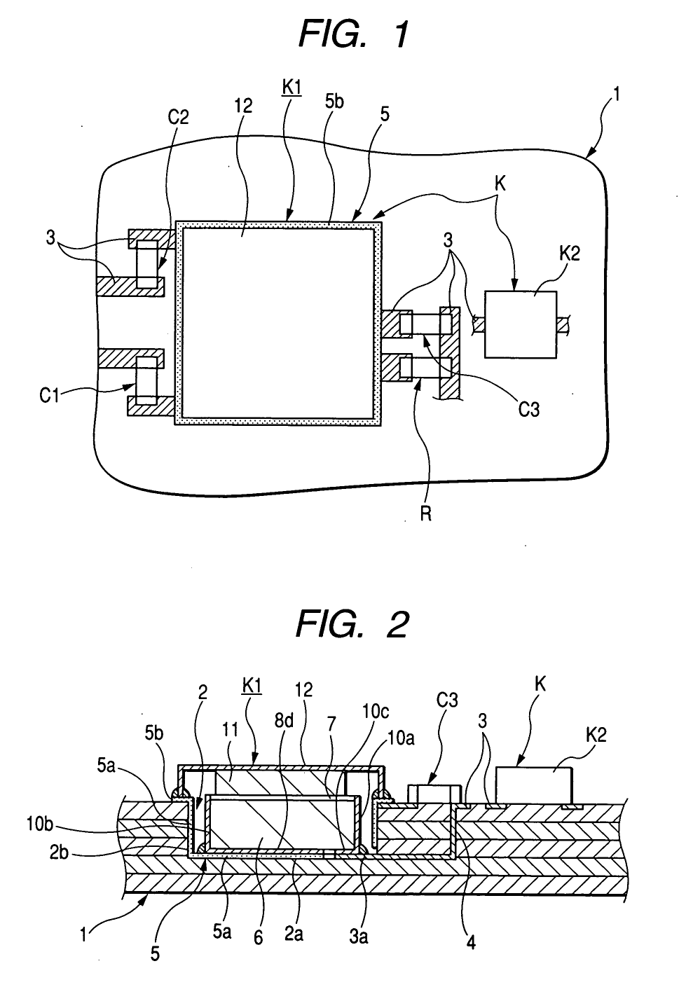

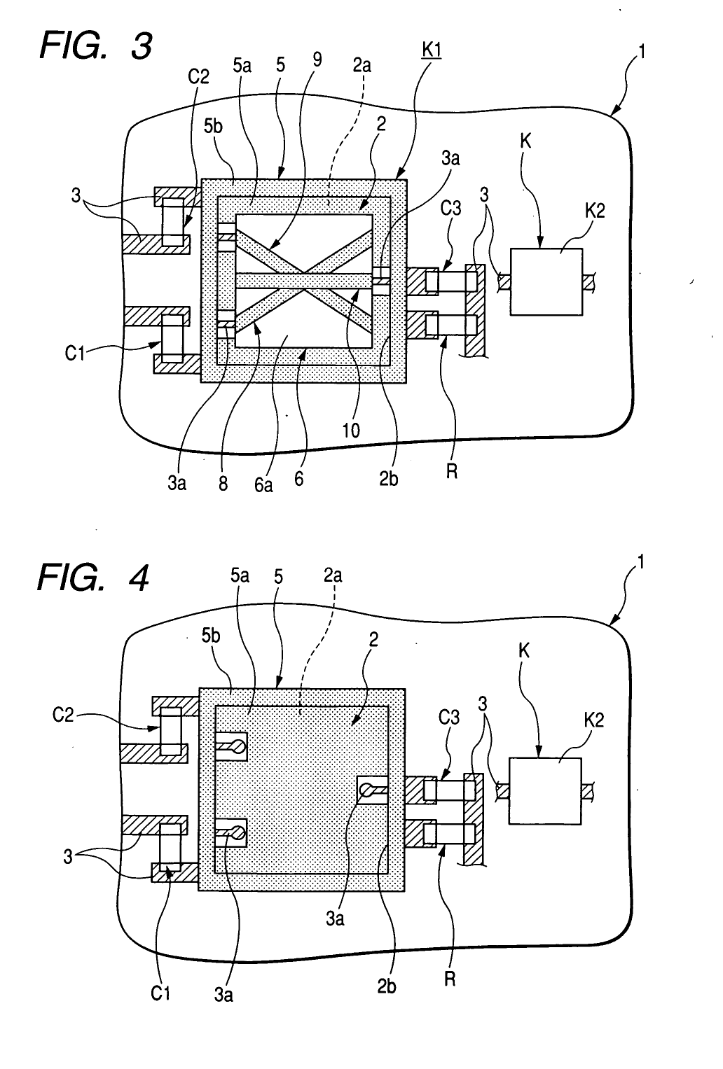

A high frequency circuit module having a non-reciprocal circuit element of the invention will now be described with reference to the drawings. FIG. 1 is a plan view showing a main body according to a first embodiment of the high frequency circuit module having the non-reciprocal circuit element of the invention. FIG. 2 is a cross-sectional view showing the main body according to the first embodiment of the high frequency circuit module having the non-reciprocal circuit element of the invention. FIG. 3 is a plan view of the main body showing a state in which an upper yoke and a magnet are removed, according to the first embodiment of the high frequency circuit module having the non-reciprocal circuit element of the invention.

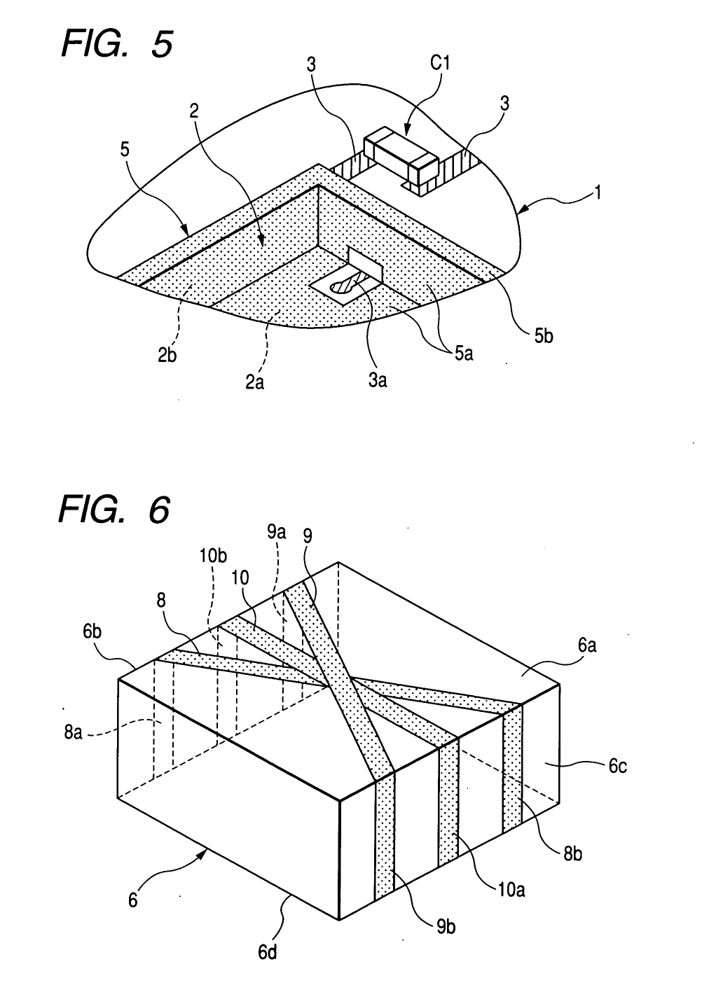

FIG. 4 is a plan view of a circuit substrate showing a state of an accommodating portion, according to the first embodiment of the high frequency circuit module having the non-reciprocal circuit element of the invention. FIG. 5 is a perspective view of the main body of the circuit substrate showing the state of the accommodating portion, according to the first embodiment of the high frequency circuit module having the non-reciprocal circuit element of the invention. FIG. 6 is a perspective view of a ferrite member, according to the first embodiment of the high frequency circuit module having the non-reciprocal circuit element of the invention. FIG. 7 is a perspective view showing a state in which the ferrite member is reversed, according to the first embodiment of the high frequency circuit module having the non-reciprocal circuit element of the invention.

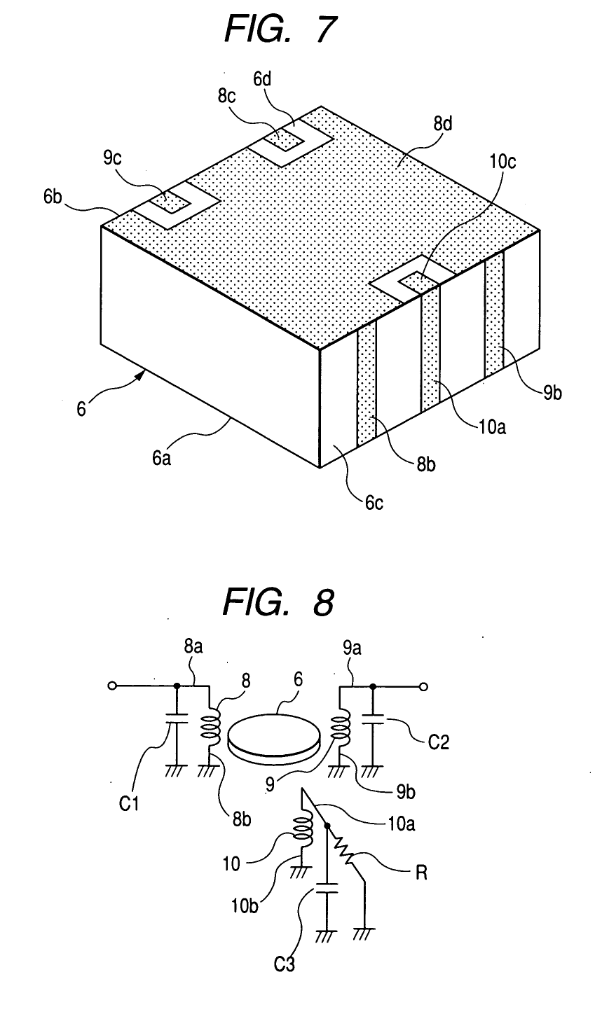

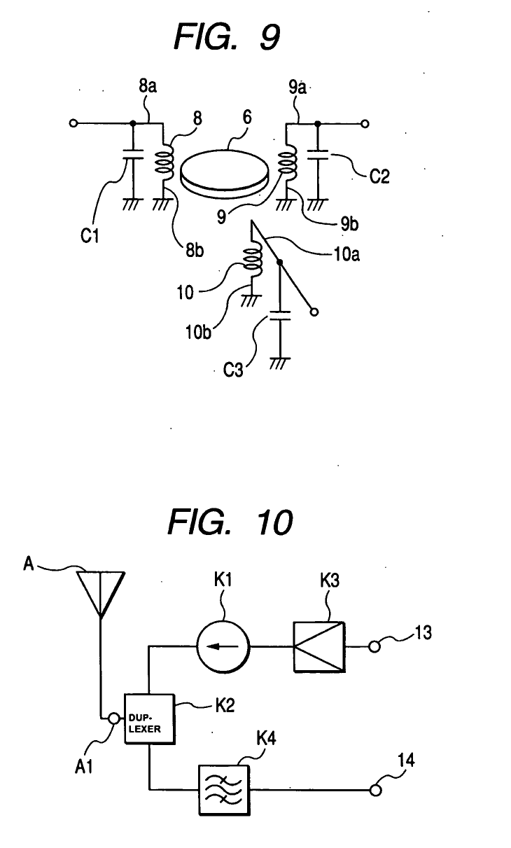

FIG. 8 is an equivalent circuit diagram of a non-reciprocal circuit element composed of an isolator, according to the high frequency circuit module having the non-reciprocal circuit element of the invention. FIG. 9 is an equivalent circuit diagram of a non-reciprocal circuit element composed of a circulator, according to the high frequency circuit module having the non-reciprocal circuit element of the invention. FIG. 10 is a circuit diagram showing a case in which the high frequency circuit module having the non-reciprocal circuit element of the invention is applied to an antenna duplexer.

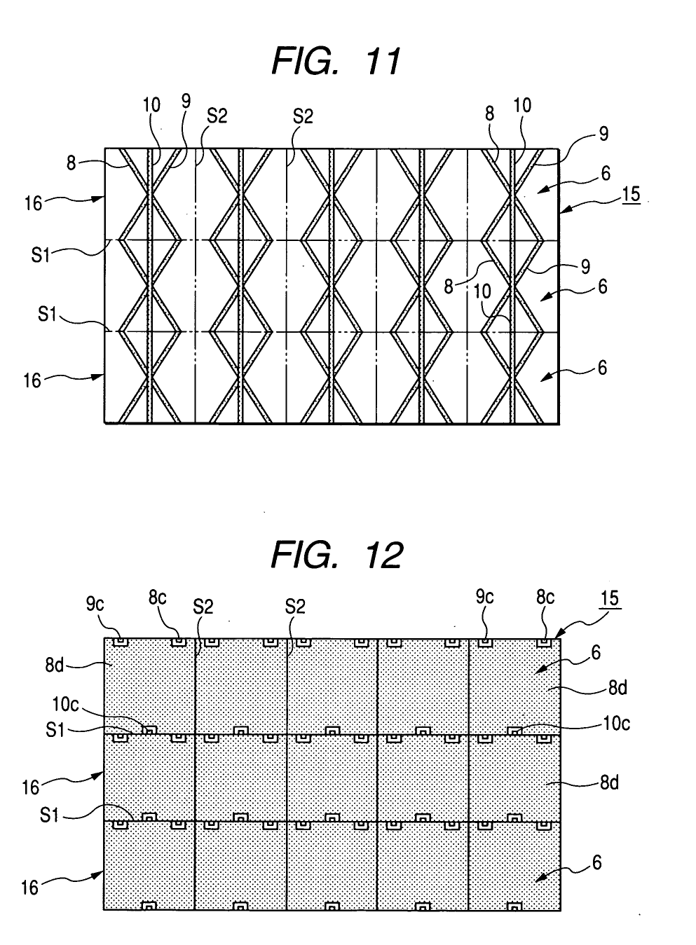

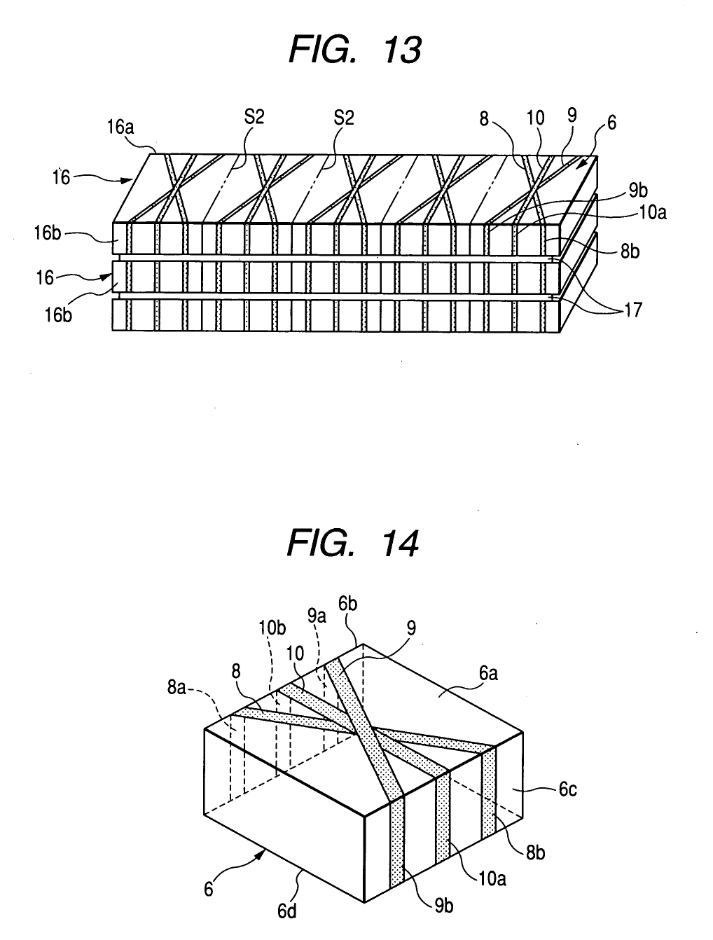

FIG. 11 is a plan view of a large-sized ferrite member for describing a method of manufacturing the non-reciprocal circuit element, according to the first embodiment of the high frequency circuit module having the non-reciprocal circuit element of the invention. FIG. 12 is a bottom view of the large-sized ferrite member for describing the method of manufacturing the non-reciprocal circuit element, according to the first embodiment of the high frequency circuit module having the non-reciprocal circuit element of the invention. FIG. 13 is a perspective view for describing the method of manufacturing the non-reciprocal circuit element, according to the first embodiment of the high frequency circuit module having the non-reciprocal circuit element of the invention.

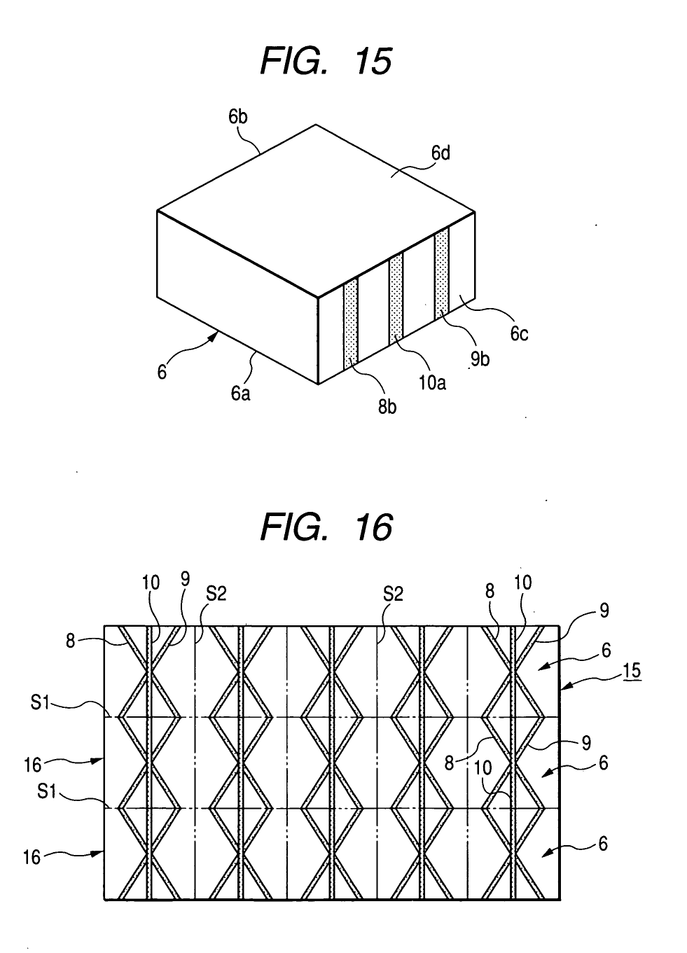

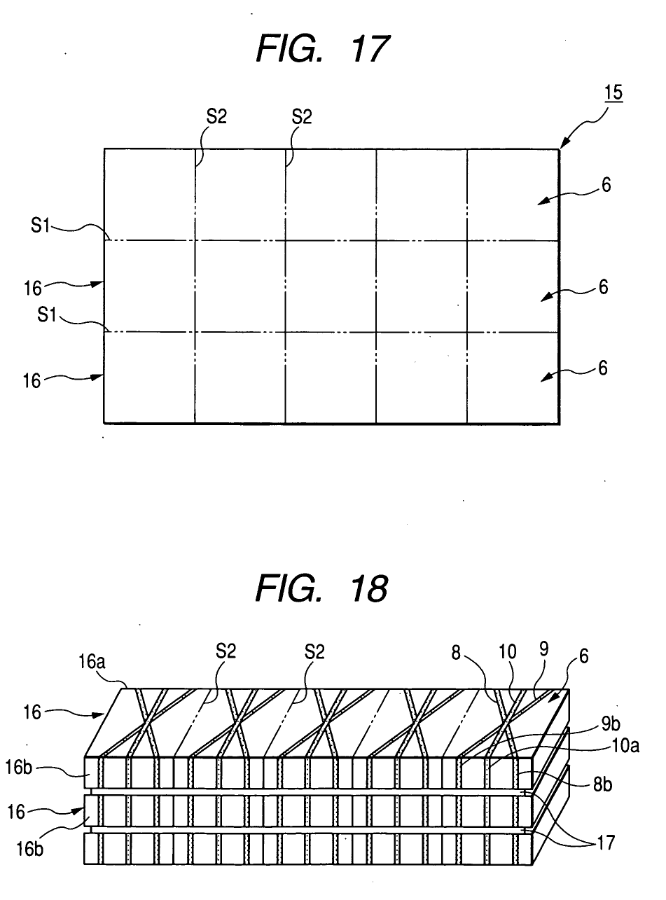

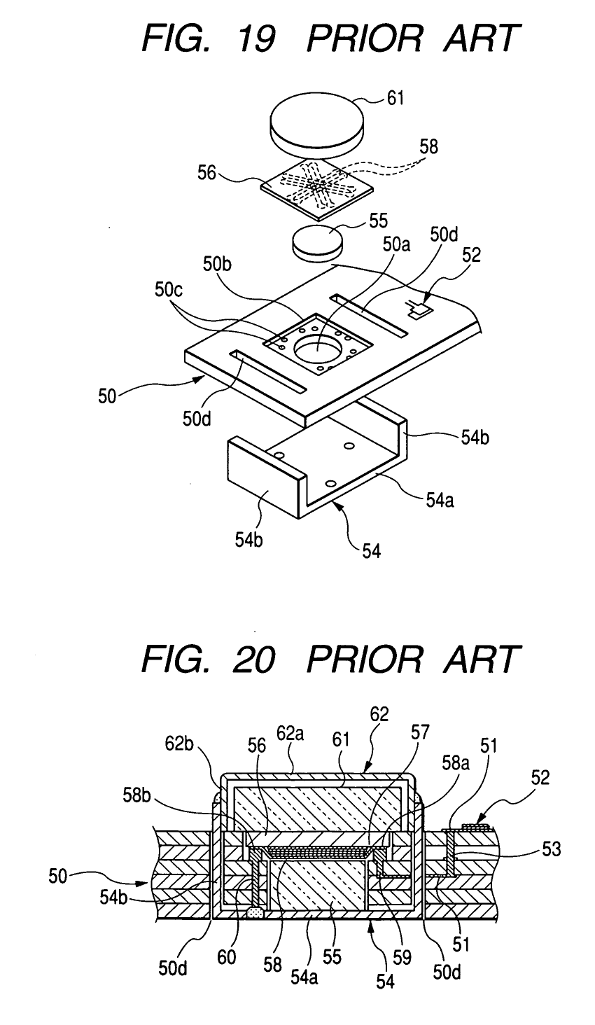

FIG. 14 is a perspective view of a ferrite member according to a second embodiment of the high frequency circuit module having the non-reciprocal circuit element of the invention. FIG. 15 is a perspective view showing a state in which the ferrite member is reversed, according to the second embodiment of the high frequency circuit module having the non-reciprocal circuit element of the invention. FIG. 16 is a plan view of a large-sized ferrite member for describing the method of manufacturing the non-reciprocal circuit element, according to the second embodiment of the high frequency circuit module having the non-reciprocal circuit element of the invention. FIG. 17 is a bottom view of the large-sized ferrite member for describing the method of manufacturing the non-reciprocal circuit element, according to the second embodiment of the high frequency circuit module having the non-reciprocal circuit element of the invention. FIG. 18 is a perspective view for describing the method of manufacturing the non-reciprocal circuit element, according to the second embodiment of the high frequency circuit module having the non-reciprocal circuit element of the invention.

Next, the structure of the high frequency circuit module having the non-reciprocal circuit element of the invention will now be described with reference to FIGS. 1 to 7. A circuit substrate 1 used in a high frequency circuit module such as an antenna duplexer is made of a multilayer substrate where a plurality of insulating plates such as LTCC (Low Temperature Co-fired Ceramic) are laminated. An accommodating portion 2 composed of a rectangular recess having a bottom surface 2a and a side surface 2b is provided at one surface side (the top surface side) of the circuit substrate 1.

Wiring patterns 3 are formed on the circuit substrate 1 and between laminated layers. A plurality of (three) connection patterns 3a that are portions of the wiring patterns 3 are formed on the bottom surface 2a of the accommodating portion 2. These connection patterns 3a are connected to the wiring patterns 3 formed on the circuit substrate 1, by connection conductors 4 made of silver or the like which is formed in the circuit substrate 1.

First, second, and third capacitors C1, C2, and C3 are composed of capacitors each formed of a chip-type capacitor, a thin film and a thick film. The first, second, and third capacitors C1, C2, and C3 are connected to the wiring patterns 3 formed on the circuit substrate 1 in the vicinity of the accommodating portion 2, and are arranged in a state dispersed at an outer periphery of the accommodating portion 2. At the same time, a resistor R is composed of a resistor formed of a chip-type resistor, a thin film, and a thick film, and is connected to the wiring pattern 3 in the vicinity of the third capacitor C3.

Although now shown in the drawing, various electronic components, such as a capacitor or a resistor, are mounted in the circuit substrate 1, in addition to the first, second, and third capacitors C1, C2, and C3 and the resistor R.

Next, the structure of a non-reciprocal circuit element K1 composed of an isolator, which is one of a high frequency circuit element K, will be described. The non-reciprocal circuit element K1 includes a lower yoke 5 formed in the circuit substrate 1; a ferrite member 6 formed of a rectangular plate made of YIG (Yttrium iron garnet); first, second and third central conductors 8, 9 and 10 formed on the ferrite member 6 in a state in which portions of them cross each other vertically via a dielectric 7; a magnet 11 disposed on the first, second and third central conductors 8, 9 and 10; an upper yoke 12 forming a magnetic closed circuit together with the lower yoke 5 in a state coupled with the lower yoke 5 and covering the magnet 11; the first, second, and third capacitors C1, C2, and C3; and the resistor R.

Furthermore, the structure of the non-reciprocal circuit element K1 will be described in detail. The grounding lower yoke 5 is formed by plating of iron or the like that is a ferromagnetic material. The lower yoke 5 has a membrane 5a made of a ferromagnetic material formed on the bottom surface 2a and the side surface 2b of the accommodating portion 2, and a ferromagnetic membrane 5b which is connected to the membrane 5a and is formed on the circuit substrate 1 so as to be located in the vicinity of the outer periphery of the accommodating portion 2.

The lower yoke 5 may be designed to accommodate a ferromagnetic plate, which is U-shaped or box-shaped in advance, in the accommodating portion 2.

In addition, the membrane 5a formed on an inner surface of the accommodating portion 2 is formed in a state in which it is not electrically connected to the connection pattern 3a. The ferromagnetic membrane 5b formed on the surface of the circuit substrate 1 is connected to the wiring pattern 3 for grounding.

As a result, one-side electrodes of the first, second, and third capacitors C1, C2, and C3 and the resistor R are connected to the hot-side wiring patterns 3 which are connected to the connection conductor 4. The other electrodes of the first, second, and third capacitors C1, C2, and C3 and the resistor R are connected to the grounding wiring patterns 3 which are connected to the ferromagnetic membrane 5b, so that they are electrically connected to a ground.

The dielectric 7, the first, second and third central conductors 8, 9 and 10 are formed on one surface side (top surface side) 6a of the ferrite member 6 directly by thin film technologies such as a deposition method and a sputtering method or thin film technologies such as printing and coating.

When the dielectric 7 is formed of a thin film and thick film technique, silicon nitride, barium titanate, lead titanate, etc. are used. When the first, second and third central conductors 8, 9 and 10 is formed by a thin film technique, silver, aluminum or the like are used. When the dielectric 7 is formed by a thick film technique, silver paste or silver-palladium paste is used.

As shown in FIGS. 6 and 7, the first, second and third central conductors 8, 9 and 10 have port portions 8a, 9a and 10a extending from one end of the central conductors; grounding portions 8b, 9b and 10b extending from the other ends. The port portions 8a, 9a and 10a and the grounding portions 8b, 9b and 10b are formed on side surfaces 6b and 6c of the rectangular ferrite member 6 which face each other. Land portions 8c, 9c and 10c connected to the portion portions 8a, 9a and 10a; and a grounding membrane 8d which is connected to the grounding portions 8b, 9b and 10b and is not electrically connected to the land portions 8c, 9c and 10c are formed on the surface 6d of the ferrite member 6 (the bottom surface).

In addition, the ferrite member 6 having the above-mentioned structure is inserted in the accommodating portion 2, the respective land portions 8c, 9c and 10c are mounted on the connection patterns 3a, and then the port portions 8a, 9a and 10a are soldered on the connection pattern 3a. The grounding membrane 8d is mounted on the membrane 5a located on the bottom surface 2a, and the grounding portions 8b, 9b and 10b are then soldered to the lower yoke 5 to be grounded.

As a result, as for the first central conductor 8, the port portion 8a is connected to one end of the first capacitor C1 via the connection pattern 3a, and the grounding portion 8b is electrically connected to the lower yoke 5. As for the second central conductor 9, the port portion 9a is connected to one end of the second capacitor C2 via the connection pattern 3a, and the grounding portion 9b is electrically connected to the lower yoke 5. Further, as for the third central conductor 10, the port portion 10a is connected to one end of the third capacitor C3 and one end of the resistor R via the connection pattern 3a, and the grounding portion 10b is electrically connected to the lower yoke 5.

The flat plate shaped magnet 11 is mounted on the first, second and third central conductors 8, 9 and 10, and the upper yoke 12 which is made of a ferromagnetic plate and is U-shaped or box-shaped is disposed to cover the magnet 11 and the accommodating portion 2.

A side portion of the upper yoke 12 is soldered on the ferromagnetic membrane 5b of the lower yoke 5, and the upper yoke 12 is magnetically coupled with the lower yoke 5. The upper yoke 12 and the lower yoke 5 form a magnetic closed circuit, thereby forming the non-reciprocal circuit element K1 composed of an isolator.

In the non-reciprocal circuit element K1 composed of the isolator as described above, as shown in an equivalent circuit diagram of FIG. 8, the port portion 8a of the first central conductor 8 is connected to one end of the first capacitor C1, so that the grounding portion 8b of the first central conductor 8 and the other end of the first capacitor C1 are electrically connected to the ground. Further, the port portion 9a of the second central conductors 9 is connected to one end of the second capacitor C2, so that the grounding portion 9b of the second central conductor 9 and the other end of the second capacitor C2 are electrically connected to the ground. Furthermore, the port portion 10a of the third central conductor 10, one end of the third capacitor C3, and one end of the resistor R are connected to each other, so that the grounding portion 10b of the third central conductor 10 and the other ends of the third capacitor C3 and the resistor R are electrically connected to the ground.

In the embodiment, although the non-reciprocal circuit element composed of the isolator has been described, a non-reciprocal circuit element composed of a circulator without the resistor R can be used.

In the non-reciprocal circuit element composed of the circulator, as shown in an equivalent circuit diagram of FIG. 9, the port portion 8a of the first central conductor 8 is connected to one end of the first capacitor C1, so that the grounding portion 8b of the first central conductor 8 and the other end of the first capacitor C1 are electrically connected to the ground. Further, the port portion 9a of the second central conductors 9 is connected to one end of the second capacitor C2, so that the grounding portion 9b of the second central conductor 9 and the other end of the second capacitor C2 are electrically connected to the ground. Furthermore, the port portion 10a of the third central conductor 10 is connected to one end of the third capacitor C3, so that the grounding portion 10b of the third central conductor 10 and the other end of the third capacitor C3 are electrically connected to the ground.

On one surface of the circuit substrate 1, the high frequency circuit element K is formed, and a duplexer K2 composed of a surface acoustic wave element is mounted. In the circuit substrate 1, although not shown, a power amplifier K3 or a SAW filter K4 composed of a surface acoustic wave element is mounted, in addition to the high frequency circuit element K composed of the non-reciprocal circuit element K1 and the duplexer K2, thereby forming an antenna duplexer having a high frequency circuit.

FIG. 10 is a circuit diagram in a case in which the high frequency circuit module of the invention is applied to an antenna duplexer. A transmitting side of the antenna duplexer has the duplexer K2 connected to an antenna terminal A1; the non-reciprocal circuit element K1 connected to the duplexer K2; the power amplifier K3 connected to the non-reciprocal circuit element K1; and a transmitting side terminal 13. A transmission signal input from the transmitting side terminal 13 is amplified by the power amplifier K3 to pass though the non-reciprocal circuit element K1.

The non-reciprocal circuit element K1 is the high frequency circuit element K for preventing that the transmission signal amplified by the power amplifier K3 is reflected at the antenna A and is then transmitted to the power amplifier K3. The non-reciprocal circuit element K1 prevents the signals from being transmitted to the power amplifier K3 from the antenna A, and the transmission signal which has passed through the non-reciprocal circuit element K1 is output from the antenna terminal A1 via the duplexer K2.

A receiving side of the antenna duplexer has the duplexer K2 connected to the antenna terminal A1; the SAW filter K4 connected to the duplexer K2; and a receiving side terminal 14. A receiving signal input from the antenna terminal A1 is output from the receiving side terminal 14 after passing through the duplexer K2 and the SAW filter K4 that is a band-pass filter.

The duplexer K2 composed of two band-pass filters (not shown) connects the antenna terminal A1 and the non-reciprocal circuit element K1 in high-frequency wise at a transmission signal frequency band. In addition, the duplexer K2 connects the antenna terminal A1 and the SAW filter K4 in high-frequency wise at a receiving signal frequency band.

Next, a method of manufacturing the non-reciprocal circuit element according to the first embodiment of the high frequency circuit module having the non-reciprocal circuit element of the invention will be described with reference to FIGS. 11 to 13. First, as shown in FIGS. 11 and 12, a large-sized rectangular ferrite member 15 is arranged, and a plurality of strip-shaped rectangular ferrite members 16 can be formed in the large-sized rectangular ferrite member 15.

In the embodiment shown in FIGS. 11 and 12., the large-sized ferrite member 15 is divided by two-dotted chain lines S1, the three strip-shaped ferrite members 16 can be formed, and each of rectangular areas defined by two-dotted chain lines S2 orthogonal to the two-dotted chain lines S1 and the two-dotted chain lines S1 forms a single ferrite member 6.

Next, as shown in FIG. 11, a plurality of groups of the first, second and third central conductors 8, 9 and 10 and the dielectrics 7 are linearly formed by thin or thick films at positions corresponding to the respective strip-shaped ferrite members 16 on the large-sized ferrite member 15. As shown in FIG. 12, land portions 8c, 9c and 10c of the first, second and third central conductors 8, 9 and 10, and the grounding membrane 8d which is not electrically connected to the land portions 8c, 9c and 10c are formed by thin or thick films at positions corresponding to the respective strip-shaped ferrite members 16 on the bottom surface of the large-sized ferrite member 15.

At this time, end portions of the port portions 8a, 9a and 10a and the grounding portions 8b, 9b and 10b of one group of the first, second and third central conductors 8, 9 and 10 is disposed to be located on the side portion of the strip-shaped ferrite member 16 in a longitudinal direction (the direction of the two-dotted chain line S1). As a result, the central conductors 8, 9 and 10 are connected to each other between the adjacent strip-shaped ferrite members 16.

Next, when the large-sized ferrite member 15 is cut by the two-dotted chain lines S1, the plurality of the strip-shaped rectangular ferrite members 16 are formed, and side surfaces 16a and 16b which are located in the longitudinal direction and face each other are formed in each of the strip-shaped rectangular ferrite member 16, as shown in FIG. 13.

After that, as shown in FIG. 13, the plurality of the strip-shaped ferrite members 16 are laminated in the same direction (in a state in which the central conductors is upward) with plate-shaped spacers 17 interposed therebetween.

Also, the plurality of the strip-shaped ferrite members 16 can be laminated without using the spacers 17.

Next, in a state that the plurality of the strip-shaped ferrite members 16 are laminated, port portions and grounding portions are formed by the same process on the side surface 16a of the strip-shaped ferrite member 16, and port portions and grounding portions are formed by the same process on the side surface 16b of the strip-shaped ferrite member 16, as shown in FIG. 13.

If so, the port portions 8a, 9a and 10a of the first, second and third central conductors 8, 9 and 10 of each of the ferrite members 6 is connected to the land portions 8c, 9c and 10c; and the grounding portion 8b, 9b and 10b of the first, second and third central conductors 8, 9 and 10 of each of the ferrite members 6 is connected to the grounding membrane 8d, as shown in FIGS. 6 and 7.

Next, when the strip-shaped ferrite members 16 are cut by the two-dotted chain lines S2, an individual ferrite member 6 shown in FIGS. 6 and 7 is formed, and the manufacture of the ferrite member 6 of the non-reciprocal circuit element of the invention is finished.

FIGS. 14 and 15 show a high frequency circuit module having a non-reciprocal circuit element according to the second embodiment of the invention. Hereinafter, the structure of the second embodiment will be described. The land portions 8c, 9c and 10c and the grounding membrane 8d formed on other surface (the bottom surface) of the ferrite member 6 in the first embodiment are removed in the second embodiment, and the other structure of the ferrite member 6 according to the second embodiment is the same as the first embodiment. Therefore, the same constituent elements as the first embodiment are denoted by the same reference numerals, and the detailed description thereof will be omitted.

Next, a method of manufacturing the non-reciprocal circuit element according to a second embodiment of the high frequency circuit module having the non-reciprocal circuit element of the invention will be described with reference to FIGS. 16 to 18. First, as shown in FIGS. 16 and 17, the large-sized rectangular ferrite member 15 is prepared, and a plurality of the strip-shaped rectangular ferrite members 16 can be formed in the large-sized rectangular ferrite member 15.

In the embodiment shown in FIGS. 16 and 17, the large-sized ferrite member 15 is divided by two-dotted chain lines S1, the three strip-shaped ferrite members 16 can be formed, and each of rectangular areas defined by two-dotted chain lines S2 orthogonal to the two-dotted chain lines S1 and the two-dotted chain lines S1 forms a single ferrite member 6.

Next, as shown in FIG. 16, a plurality of groups of the first, second and third central conductors 8, 9 and 10 and the dielectrics 7 are linearly formed by thin or thick films at positions corresponding to the respective strip-shaped ferrite members 16 on the large-sized ferrite member 15. As shown in FIG. 17, nothing is formed on the bottom surface of the large-sized ferrite member 15.

At this time, end portions of the port portions 8a, 9a and 10a and the grounding portions 8b, 9b and 10b of each of the plurality of groups of the first, second and third central conductors 8, 9 and 10 are disposed to be located at the side portion of the strip-shaped ferrite member 16 in a longitudinal direction (the direction of the two-dotted chain line S1). As a result, the central conductors 8, 9 and 10 are connected to each other between the adjacent strip-shaped ferrite members 16.

Next, when the large-sized ferrite member 15 is cut by the two-dotted chain line S1, the plurality of the strip-shaped rectangular ferrite members 16 are formed, and side surfaces 16a and 16b which are located in the longitudinal direction and face each other are formed in each of the strip-shaped rectangular ferrite members 16, as shown in FIG. 18.

After that, as shown in FIG. 18, the plurality of the strip-shaped ferrite members 16 are laminated in the same direction (in a state in which the central conductor is upward) with plate-shaped spacers 17 interposed therebetween.

Also, the plurality of the strip-shaped ferrite members 16 can be laminated without using the spacers 17.

Next, in a state that the plurality of the strip-shaped ferrite members 16 are laminated, port portions and grounding portions are formed by the same process on the side surface 16a of the strip-shaped ferrite member 16, and port portions and grounding portions are formed by the same process on the side surface 16b of the strip-shaped ferrite member 16, as shown in FIG. 18.

If so, the port portions 8a, 9a and 10a and the grounding portions 8b, 9b and 10b are formed in the first, second and third central conductors 8, 9 and 10 of each of the ferrite members 6, as shown in FIGS. 14 and 15.

Next, when the strip-shaped ferrite members 16 are cut by the two-dotted chain lines S2, an individual ferrite member 6 shown in FIGS. 14 and 15 is formed, and the manufacture of the ferrite member 6 of the non-reciprocal circuit element of the invention is finished.

Although the strip-shaped ferrite member 16 is formed using the large-sized ferrite member 15 in the above-mentioned embodiments, the strip-shaped ferrite member 16 may be formed in advance, thereby forming the central conductors in the strip-shaped ferrite member 16.

The high frequency circuit module having a non-reciprocal circuit element of the invention includes a circuit substrate that has a wiring pattern and that is composed of a multilayer substrate in which a plurality of insulating plates are laminated; a high frequency circuit element having the non-reciprocal circuit element provided on the circuit substrate; and a high frequency circuit formed on the circuit substrate. In addition, an accommodating portion composed of a recess having a bottom surface is provided in the circuit substrate; and the non-reciprocal circuit element includes a lower yoke composed of ferromagnetic membranes formed on a side surface of the accommodating portion and the bottom surface; a ferrite member accommodated in the accommodating portion; first, second and third central conductors disposed on the ferrite member such that portions of the first, second and third central conductors cross each other vertically via a dielectric; a magnet disposed on the first, second and third central conductors such that the first, second and third central conductors are interposed between the ferrite member and the magnet; and an upper yoke disposed to cover the magnet and the accommodating portion for forming a magnetic closed circuit together with the lower yoke.

When the lower yoke is formed of the ferromagnetic membrane, the number of essential elements is less, productivity is high, a cost is low, and the non-reciprocal circuit element has a small size in a thickness direction, compared to the lower yoke composed of a metal plate in the related art.

Further, since the lower yoke is formed by performing iron plating, the lower yoke can be easily formed, which leads to good productivity.

Further, since silver plating is performed on the lower yoke which has been subjected to the iron plating, electrical resistance of the lower yoke can decreases, so that current flow in the lower yoke gets better, thereby achieving superior performance.

Further, the ferromagnetic membrane made of the same material as the lower yoke is formed on the surface of the circuit substrate located in the vicinity of an outer periphery of the accommodating portion, and the upper yoke is coupled at a location of the ferromagnetic membrane. Thus, the coupling between the upper yoke and the lower yoke becomes easier, thereby achieving good assembly.

Further, since the central conductors and the dielectric are formed on the ferrite member directly by thick films, the conventional insulating plate is not required. Thus, the number of essential elements is less, productivity is high, a cost is low, and the non-reciprocal circuit element has a small size in a thickness direction.

Each of the central conductors has a port portion extending from one end of each central conductor and a grounding portion extending from the other end of each central conductor, the port portion and the grounding portion are formed on a side surface of the ferrite member, and the grounding portion is connected to the lower yoke. Therefore, the base portion can be easily connected to the lower yoke, which leads to good productivity.

Further, the ferrite member is formed of a rectangular plate, and the port portion and the grounding portion are formed on the side surfaces of the ferrite member facing each other. Therefore, the port portion and the grounding portion can be easily formed on the ferrite member, thereby achieving good productivity.

A plurality of connection patterns, which are not electrically connected to the lower yoke, are formed on the bottom surface of the accommodating portion, a plurality of capacitors, which are respectively connected to the plurality of connection patterns, are formed in the circuit substrate, and the port portion is connected to the connection pattern. Therefore, the port portion can be easily connected to the connection pattern, thereby achieving good productivity.

Further, the capacitor is formed on the surface of the circuit substrate, and the capacitor and the connection pattern are connected to each other by a connection conductor formed in an inner layer of the circuit substrate. Therefore, the capacitor can be arranged at an arbitrary location of the surface of the circuit substrate, so that a flexible layout of the circuit substrate can be obtained.

Further, the high frequency circuit element has a duplexer composed of a surface acoustic wave element, and the duplexer is mounted on the circuit substrate, thereby constructing an antenna duplexer serving as a transmitting and receiving antenna. Therefore, the height of the duplexer mounted on the circuit substrate is substantially equal to that of the non-reciprocal circuit element assembled in the circuit substrate in a thickness direction, thereby achieving a small-sized antenna duplexer.

1. A high frequency circuit module having a non-reciprocal circuit element, comprising:
a circuit substrate that has a wiring pattern and that is composed of a multilayer substrate in which a plurality of insulating plates are laminated;
a high frequency circuit element having the non-reciprocal circuit element provided on the circuit substrate; and
a high frequency circuit formed on the circuit substrate,
wherein an accommodating portion composed of a recess having a bottom surface is provided in the circuit substrate; and
the non-reciprocal circuit element includes a lower yoke composed of ferromagnetic membranes formed on a side surface of the accommodating portion and the bottom surface; a ferrite member accommodated in the accommodating portion; first, second and third central conductors disposed on the ferrite member such that portions of the first, second and third central conductors cross each other vertically via a dielectric; a magnet disposed on the first, second and third central conductors such that the first, second and third central conductors are interposed between the ferrite member and the magnet; an upper yoke disposed to cover the magnet and the accommodating portion for forming a magnetic closed circuit together with the lower yoke.

2. The high frequency circuit module having a non-reciprocal circuit element according to claim 1,
wherein the lower yoke is formed by performing iron plating.

3. The high frequency circuit module having a non-reciprocal circuit element according to claim 2,
wherein silver plating is performed on the lower yoke which has been subjected to the iron plating.

4. The high frequency circuit module having a non-reciprocal circuit element according to claim 1,
wherein a ferromagnetic membrane made of the same material as the lower yoke is formed on at#e surface of the circuit substrate located in the vicinity of an outer periphery of the accommodating portion, and the upper yoke is coupled at a location of the ferromagnetic membrane.

5. The high frequency circuit module having a non-reciprocal circuit element according to claim 1,
wherein the central conductors and the dielectric is formed on the ferrite member directly by thick films.

6. The high frequency circuit module having a non-reciprocal circuit element according to claim 1,
wherein each of the central conductors has a port portion extending from one end of each central conductor and a grounding portion extending from the other end of each central conductor, the port portion and the grounding portion are formed on a side surface of the ferrite member, and the grounding portion is connected to the lower yoke.

7. The high frequency circuit module having a non-reciprocal circuit element according to claim 6,
wherein the ferrite member is formed of a rectangular plate, and the port portion and the grounding portion are formed on side surfaces of the ferrite member facing each other.

8. The high frequency circuit module having a non-reciprocal circuit element according to claim 6,
wherein a plurality of connection patterns, which are not electrically connected to the lower yoke, are formed on the bottom surface of the accommodating portion, a plurality of capacitors, which are respectively connected to the plurality of connection patterns, are formed in the circuit substrate, and the port portion is connected to the connection pattern.

9. The high frequency circuit module having a non-reciprocal circuit element according to claim 8,
wherein the capacitor is formed on a surface of the circuit substrate, and the capacitor and the connection pattern are connected to each other by a connection conductor formed in an inner layer of the circuit substrate.

10. The high frequency circuit module having a non-reciprocal circuit element according to claim 1,
wherein the high frequency circuit element has a duplexer composed of a surface acoustic wave element, and the duplexer is mounted on the circuit substrate, thereby constructing an antenna duplexer serving as an transmitting and receiving antenna.
